(19) United States
(12) Patent Application Publication
(10) Pub. No.: US 2022/0413021 A1
(43) Pub. Date: Dec. 29, 2022

(54) CURRENT SIGNAL SEGMENTATION ALGORITHM

(71) Applicants: JIANGSU ELECTRIC POWER INFORMATION TECHNOLOGY CO., LTD., Nanjing (CN); POWER COMPANY LIMITED, Nanjing (CN)

(72) Inventors: Jie YUAN, Nanjing (CN); Lei XU, Nanjing (CN); Peng WU, Nanjing (CN)

(73) Assignees: JIANGSU ELECTRIC POWER INFORMATION TECHNOLOGY CO., LTD., Nanjing (CN); POWER COMPANY LIMITED, Nanjing (CN)

(21) Appl. No.: 17/764,997

(22) PCT Filed: Jun. 28, 2020
(86) PCT No.: PCT/CN2020/098506

§ 371 Date: Mar. 30, 2022

(30) Foreign Application Priority Data
May 18, 2020 (CN) 202010417871.9

(51) Int. Cl. G01R 19/25; G06K 9/00

(52) U.S. Cl. CPC G01R 19/25; G06K 9/00523; G06K 9/00536

(57) ABSTRACT

A current signal segmentation algorithm is provided. The segmentation algorithm divides a current signal waveform into mutually different segments according to a physical feature thereof, extracts shape distribution, statistical and harmonic features of the segments, and calculates a similarity between a segment pair. The segmentation algorithm includes the following steps: segmenting a current signal to separate a standby current and an overshoot current, only leaving a working current; extracting a shape distribution feature of a working current segment; extracting a statistical feature of the working current segment; extracting a harmonic feature of the working current segment; calculating a similarity between a segment pair; and deriving a maximum clique set in a similarity graph through a maximum clique search algorithm as a class from automatic segmentation. The algorithm can quickly and accurately classify current signals generated by different electrical appliances in different working states so as to facilitate subsequent processing.

### TECHNICAL FIELD

The present disclosure belongs to the field of noninvasive load monitoring (NILM), and relates to a feature extraction method for a current signal, in particular to a current signal segmentation algorithm.

### BACKGROUND

In recent years, due to the continuous development of smart grid technologies, the application of lean and intelligent analysis of electrical signals has become increasingly extensive. For example, NILM technology analyzes integrated voltage and current through feature extraction and machine learning (ML) algorithms and monitors appliance usage without submeters. Many feature extraction methods were proposed to extract wavelet features, voltage-current (V-I) trajectories, current harmonics, active/reactive power and automatically learned deep features for NILM. According to Non-Intrusive Load Monitoring Using Semi-Supervised Machine Learning and Wavelet Design, signal features are extracted by matching a set of wavelets to load types through wavelet designing and the Procrustes analysis. The wavelets used according to different load types need to be selected from a large number of wavelets, which limits the use of the method for unknown electrical appliances. Different V-I trajectory family features are extracted from a V-I trajectory picture to describe the working states of different electrical appliances. The V-I trajectory features include looping direction, enclosed area, nonlinearity of mean curve, number of self-intersections, slope of middle segment and area of right and left segments, etc. However, the noise signal has a great influence on the V-I trajectory, which can easily lead to the mutation of the V-I trajectory features. The current harmonic features such as mode and mode ratio are extracted from high-frequency current harmonics to distinguish different electrical appliances. However, in order to improve the extraction effect, the sampling frequency of the signal is generally required to reach 1 MHZ or above, which brings a huge obstacle to the application of current harmonic features. According to Non-Intrusive Load Monitoring by Novel Neuro-Fuzzy Classification Considering Uncertainties, cluster analysis is performed on the active/reactive power data of various household appliances, and various centers are regarded as the power load features of each appliance for training and identification. However, it is hard to distinguish electrical appliances with similar active/reactive power features. Deep learning (DL) methods require a large amount of labeled data for supervised or semi-supervised learning, but labeled data is often costly and scarce in practical scenarios, which greatly limits the development of this method. Although the power feature is found in many works, for NILM, the current feature is more effective than the power feature.

### SUMMARY

An objective of the present disclosure is to provide a current signal segmentation algorithm. The present disclosure accurately depicts current signals of different electrical appliances in different states by extracting distinguishing features of the current signals, so as to facilitate subsequent processing.

The objective of the present disclosure is achieved by the following technical solution. A current signal segmentation algorithm, accurately depicting current signals of different electrical appliances in different states by extracting distinguishing features of the current signals, includes the following steps:

1) segmenting a current signal to separate a standby current and an overshoot current, only leaving a working current;

2) extracting a shape distribution feature of a working current segment;

3) extracting a statistical feature of the working current segment;

4) extracting a harmonic feature of the working current segment;

5) calculating a similarity between a segment pair; and

6) deriving a maximum clique set in a similarity graph through a maximum clique search algorithm as a class from automatic segmentation.

In the present disclosure, the segmenting a current signal to separate a standby current and an overshoot current, only leaving a working current includes:

step 1: sampling all vertices:

where, an original signal is denoted as S, which has a length of L_{S}; sampled points are denoted as P; and every Nᵥ points are sampled to obtain a vertex Vₖ;

Vₖ=max{Pᵢ}−min{Pⱼ}, where (k−1)*Nᵥ+1≤i, j≤k*Nᵥ, k*N≤Lₛ;

step 2: starting recording when the vertex obtained by down-sampling satisfies a condition C₁: (Vₖ>Vₖ₋₁ and Vₖ>Vₖ₊₁)or(Vₖ>Vₖ₋₁ and Vₖ<Vₖ₊₁);

step 3: merging two neighboring segments that satisfy C2: |s̅e̅c̅ₘ−s̅e̅c̅ₘ₋₁|<max(|S̅e̅c̅ₘ|,|S̅e̅c̅ₘ₋₁|)/10; and

step 4: detecting a standby current and an overshoot current:

determining a current of an i-th segment to be in a standby state when the current of the i-th segment satisfies the following condition:

S̅e̅c̅ᵢ̅<P10{Vₖ}

determining the i-th segment Secᵢ to be an overshoot current segment when the i-th segment satisfies the following condition:

S̅e̅c̅ᵢ̅>2·max(S̅e̅c̅ᵢ̅₋̅₁̅,S̅e̅c̅ᵢ̅₊̅₁̅)

The step of extracting a shape distribution feature of a working current segment includes:

step 1: extracting a value distribution class feature:

$${S}_{i}^{1} ( Se {c}_{k} ) = \# ( {P}_{j} ) / \# ( Se {c}_{k} ) , i = 1 , 2 , 3 , 4 , 5$$

$${P}_{j} ∈ S e {c}_{k} and {P}_{j} ∈ [ min ( S e {c}_{k} ) + \frac{max ( S e {c}_{k} ) - min ( S e {c}_{k} )}{5} \cdot ( i - 1 ) , min ( {Sec}_{k} ) + \frac{max ( S e {c}_{k} ) - min ( S e {c}_{k} )}{5} \cdot i ) ,$$

where, #( ) denotes a number of points in the set in parentheses, and k denotes a k-th effective segment; and

step 2: extracting a spatial distribution class feature:

$${S}_{i}^{2} ( Se {c}_{k} ) = 2 \cdot \# ( {P}_{j} ) / \# ( Se {c}_{k} ) , i = 1 , 2 , 3 , 4 , 5$$

$${P}_{j} ∈ S e {c}_{k} and {P}_{j} \geq median ( {Sec}_{k} ) and {P}_{j} ∈ [ \text{} {Sec}_{k}^{start} + \frac{{Sec}_{k}^{end} - {Sec}_{k}^{start}}{5} \cdot ( i - 1 ) , {Sec}_{k}^{start} + \frac{{Sec}_{k}^{end} - {Sec}_{k}^{start}}{5} \cdot i ) ,$$

where, median(Secₖ) denotes a median of values of all points in the k-th effective segment Secₖ.

The step of extracting a statistical feature of the working current segment includes:

step 1: labeling all vertices in a k-th effective segment Secₖ; and

step 2: calculating a mean, a median and a standard deviation of values of all the vertices.

The step of extracting a harmonic feature of the working current segment includes:

step 1: harmonically transforming all points in a k-th effective segment Secₖ; and

step 2: using first 16 harmonics;

$$f ( i ) = F ( i ) / {\sum }_{i = 0}^{16} F ( i ) i = 0 , 1 , 2 , … 16 \qquad ( 15 )$$

where, F(i) denotes a value of an i-th harmonic.

The step of calculating a similarity between a segment pair includes:

assigning two segments each as A and B:

step 1: calculating 6 sub similarities between the two segments:

$$Sim {i}_{1} ( A , B ) = \frac{{\sum }_{i = 1}^{5} min ( {S}_{i}^{1} ( A ) , {S}_{i}^{1} ( B ) )}{{\sum }_{i = 1}^{5} max ( {S}_{i}^{1} ( A ) , {S}_{i}^{1} ( B ) )}$$

$$Sim {i}_{2} ( A , B ) = \frac{{\sum }_{i = 1}^{5} min ( {S}_{i}^{2} ( A ) , {S}_{i}^{2} ( B ) )}{{\sum }_{i = 1}^{5} max ( {S}_{i}^{2} ( A ) , {S}_{i}^{2} ( B ) )}$$

$$Sim {i}_{3} ( A , B ) = \frac{min ( {\overline{Sec}}_{A} , {\overline{Sec}}_{B} )}{max ( {\overline{Sec}}_{A} , {\overline{Sec}}_{B} )}$$

$$Sim {i}_{4} ( A , B ) = \frac{min ( {σ}_{S e {c}_{A}} / {\overline{Sec}}_{A} , {σ}_{S e {c}_{B}} / {\overline{Sec}}_{B} )}{max ( {σ}_{S e {c}_{A}} / {\overline{Sec}}_{A} , {σ}_{S e {c}_{B}} / {\overline{Sec}}_{B} )}$$

$$Sim {i}_{5} ( A , B ) = \frac{min ( median ( {Sec}_{A} ) , median ( {Sec}_{B} ) )}{max ( median ( {Sec}_{A} ) , median ( {Sec}_{B} ) )}$$

$$Sim {i}_{6} ( A , B ) = \frac{{\sum }_{i = 0}^{16} min ( {f}_{i} ( A ) , {f}_{i} ( B ) )}{{\sum }_{i = 0}^{16} max ( {f}_{i} ( A ) , {f}_{i} ( B ) )} ,$$

and

step 2: calculating a combined similarity:

$$Similarity ( A , B ) = {\prod }_{i = 1}^{6} {Simi}_{i} ( A , B ) .$$

The step of deriving a maximum clique set in a similarity graph through a maximum clique search algorithm as a class from automatic segmentation includes:

denoting the similarity graph as G=(V,E), where V denotes a segment set of the current signal, and E denotes a similarity matrix, which is a symmetrical similarity matrix; and denoting a similarity threshold as Sₜₕ and a class set as C, cᵢ∈C,vₖ∈cᵢ, k∈{1,2, . . . |V|};

step 1: initializing Cᵢ=i and e_{i, i}=0;

step 2: when the class set C is updated:

setting a similarity between all vertexes belonging to a current class and the current class to 0;

setting a similarity e_{i,j} between all vertexes belonging to the current class in E to 0;

calculating a minimum similarity min_simi_{i,clique} between all the vertexes and the vertexes in the current class;

taking a maximum value max(min_simi_{i,clique}) of all min_simi_{i,clique}; if max(min_simi_{i,clique})<Sₜₕ and max(E)>Sₜₕ, then:

creating a new class composed of initial members that two vertices corresponding to max(E);

setting a class label to a smaller value of the two vertices; and

deleting an origin class of the two vertices; or if max(min_simi_{i,clique})≥Sₜₕ, then:

joining a vertex with the maximum value into the current class, and deleting an origin class thereof; and

step 3: renumbering the class label, and updating a class number.

The present disclosure classifies a current signal of an electrical appliance, extracts spatial, temporal, and frequency domain features of each segment, calculates a similarity between a segment pair, and derives a maximum clique set in a similarity graph through a maximum clique search algorithm. The present disclosure can quickly and accurately classify current signals generated by different electrical appliances in different working states, so as to facilitate subsequent processing.

### BRIEF DESCRIPTION OF THE DRAWINGS

FIG. 1 shows an original signal according to the present disclosure;

FIG. 2 shows an effective segment of the current signal according to the present disclosure; and

FIG. 3 shows an automatic segmentation effect according to the present disclosure.

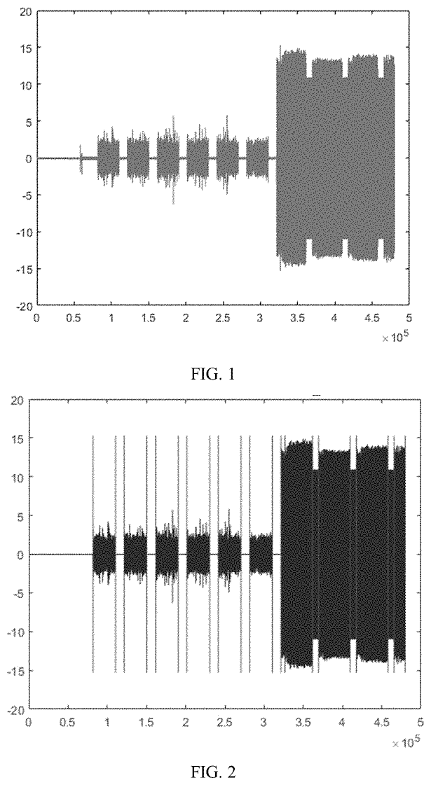

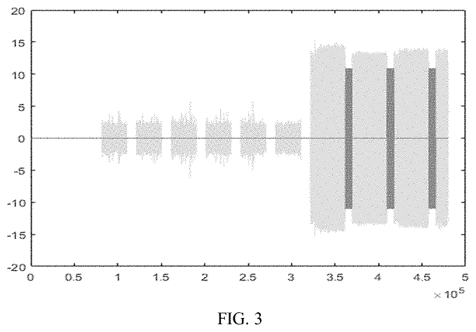

### DETAILED DESCRIPTION OF THE EMBODIMENTS

A current signal segmentation algorithm accurately depicts current signals of different electrical appliances in different states by extracting distinguishing features of the current signals, and includes the following steps:

1) Segment a current signal to separate a standby current and an overshoot current, only leaving a working current.

2) Extract a shape distribution feature of a working current segment.

3) Extract a statistical feature of the working current segment.

4) Extract a harmonic feature of the working current segment.

5) Calculate a similarity between a segment pair.

6) Derive a maximum clique set in a similarity graph through a maximum clique search algorithm as a class from automatic segmentation.

The step of segmenting a current signal to separate a standby current and an overshoot current, only leaving a working current includes:

Step 1: Sample all vertices:

where, an original signal is denoted as S, which has a length of L_{S}; and every N_{V} points are sampled to obtain a vertex Vₖ:

Vₖ=max{Pᵢ}−min{Pⱼ}, where, (k−1)*Nᵥ+1≤i, j≤k*Nᵥ,k*N≤Lₛ.

Step 2: Start recording when the vertex obtained by down-sampling satisfies a condition C₁: (Vₖ>Vₖ₋₁ and Vₖ>Vₖ₊₁)or(Vₖ>Vₖ₋₁ and Vₖ<Vₖ₊₁).

Step 3: Merge two neighboring segments that satisfy C₂: |s̅e̅c̅ₘ−s̅e̅c̅ₘ₋₁|<max(|S̅e̅c̅ₘ|,|S̅e̅c̅ₘ₋₁|)/10

where, S̅e̅c̅ₘ̅denotes a mean of all points sampled in an m-th segment.

Step 4: Detect a standby current and an overshoot current:

Determine a current of an i-th segment to be in a standby state when the current of the i-th segment satisfies the following condition:

S̅e̅c̅ᵢ̅<P10{Vₖ}

Determine the i-th segment Secᵢ to be an overshoot current segment when the i-th segment satisfies the following condition:

S̅e̅c̅ᵢ̅>2·max(S̅e̅c̅ᵢ̅₋̅₁̅,S̅e̅c̅ᵢ̅₊̅₁̅)

The step of extracting a shape distribution feature of a working current segment includes:

Step 1: Extract a value distribution class feature:

$${S}_{i}^{1} ( Se {c}_{k} ) = \# ( {P}_{j} ) / \# ( Se {c}_{k} ) , i = 1 , 2 , 3 , 4 , 5$$

$${P}_{j} ∈ S e {c}_{k} and {P}_{j} ∈ [ min ( S e {c}_{k} ) + \frac{max ( S e {c}_{k} ) - min ( S e {c}_{k} )}{5} \cdot ( i - 1 ) , min ( {Sec}_{k} ) + \frac{max ( S e {c}_{k} ) - min ( S e {c}_{k} )}{5} \cdot i ) ,$$

where, #( ) denotes a number of points in the set in parentheses, and k denotes a k-th effective segment.

Step 2: Extract a spatial distribution class feature:

$${S}_{i}^{2} ( Se {c}_{k} ) = 2 \cdot \# ( {P}_{j} ) / \# ( Se {c}_{k} ) , i = 1 , 2 , 3 , 4 , 5$$

$${P}_{j} ∈ S e {c}_{k} and {P}_{j} \geq median ( {Sec}_{k} ) and {P}_{j} ∈ [ \text{} {Sec}_{k}^{start} + \frac{{Sec}_{k}^{end} - {Sec}_{k}^{start}}{5} \cdot ( i - 1 ) , {Sec}_{k}^{start} + \frac{{Sec}_{k}^{end} - {Sec}_{k}^{start}}{5} \cdot i ) ,$$

where, median(Secₖ) denotes a median of values of all points in the k-th effective segment Secₖ.

The step of extracting a statistical feature of the working current segment includes:

Step 1: Label all vertices in the k-th effective segment Secₖ.

Step 2: Calculate a mean, a median and a standard deviation of values of all the vertices. The step of extracting a harmonic feature of the working current segment includes:

Step 1: Harmonically transform all points in a k-th effective segment Secₖ.

Step 2: Use first 16 harmonics:

$$f ( i ) = F ( i ) / {\sum }_{i = 0}^{16} F ( i ) i = 0 , 1 , 2 , … 16$$

where, F(i) denotes a value of an i-th harmonic.

The step of calculating a similarity between a segment pair includes:

Let two segments be A and B:

Step 1: Calculate 6 subsimilarities between the two segments:

$$Sim {i}_{1} ( A , B ) = \frac{{\sum }_{i = 1}^{5} min ( {S}_{i}^{1} ( A ) , {S}_{i}^{1} ( B ) )}{{\sum }_{i = 1}^{5} max ( {S}_{i}^{1} ( A ) , {S}_{i}^{1} ( B ) )}$$

$$Sim {i}_{2} ( A , B ) = \frac{{\sum }_{i = 1}^{5} min ( {S}_{i}^{2} ( A ) , {S}_{i}^{2} ( B ) )}{{\sum }_{i = 1}^{5} max ( {S}_{i}^{2} ( A ) , {S}_{i}^{2} ( B ) )}$$

$$Sim {i}_{3} ( A , B ) = \frac{min ( {\overline{Sec}}_{A} , {\overline{Sec}}_{B} )}{max ( {\overline{Sec}}_{A} , {\overline{Sec}}_{B} )}$$

$$Sim {i}_{4} ( A , B ) = \frac{min ( {σ}_{S e {c}_{A}} / {\overline{Sec}}_{A} , {σ}_{S e {c}_{B}} / {\overline{Sec}}_{B} )}{max ( {σ}_{S e {c}_{A}} / {\overline{Sec}}_{A} , {σ}_{S e {c}_{B}} / {\overline{Sec}}_{B} )}$$

$$Sim {i}_{5} ( A , B ) = \frac{min ( median ( {Sec}_{A} ) , median ( {Sec}_{B} ) )}{max ( median ( {Sec}_{A} ) , median ( {Sec}_{B} ) )}$$

$$Sim {i}_{6} ( A , B ) = \frac{{\sum }_{i = 0}^{16} min ( {f}_{i} ( A ) , {f}_{i} ( B ) )}{{\sum }_{i = 0}^{16} max ( {f}_{i} ( A ) , {f}_{i} ( B ) )} .$$

Step 2: Calculate a combined similarity:

$$Similarity ( A , B ) = {\prod }_{i = 1}^{6} {Simi}_{i} ( A , B )$$

The step of deriving a maximum clique set in a similarity graph through a maximum clique search algorithm as a class from automatic segmentation includes:

Denote the similarity graph as G=(V,E), where V denotes a segment set of the current signal, and E denotes a similarity matrix, which is a symmetrical similarity matrix; and denote a similarity threshold as Sₜₕ and a class set as C, cᵢ∈C,vₖ∈cᵢ,k∈{1,2, . . . |V|}.

Step 1: Initialize cᵢ=i and e_{i,i}=0;

Step 2: When the class set C is updated:

Set a similarity between all vertexes belonging to a current class and the current class to 0;

Set a similarity e_{i,j} between all vertexes belonging to the current class in E to 0.

Calculate a minimum similarity between all the vertexes and the vertexes in the current class.

Take a maximum value max (min_simi_{i,clique}) of all min_simi_{i,clique}.

If max(min_simi_{i,clique})<Sₜₕ and max(E)>Sₜₕ, then:
create a new class composed of initial members that two vertices corresponding to max(E).
Set a class label to a smaller value of the two vertices.
Delete an origin class of the two vertices.

If max(min_simi_{i,clique})≥Sₜₕ, then:
join a vertex with the maximum value into the current class, and deleting an origin class thereof.

Step 3: Renumber the class label, and updating a class number.

The present disclosure can quickly and accurately classify current signals generated by different electrical appliances in different working states, so as to facilitate subsequent processing.

What is claimed is:

1. A current signal segmentation algorithm, wherein accurately depicting current signals of different electrical appliances in different states by extracting distinguishing features of the current signals comprises the following steps:
1) segmenting a current signal to separate a standby current and an overshoot current, only leaving a working current;
2) extracting a shape distribution feature of a working current segment;
3) extracting a statistical feature of the working current segment;
4) extracting a harmonic feature of the working current segment;
5) calculating a similarity between a segment pair; and
6) deriving a maximum clique set in a similarity graph through a maximum clique search algorithm as a class from an automatic segmentation.

2. The current signal segmentation algorithm according to claim 1, wherein step 1) comprises:
step 1: sampling all vertices:
wherein, an original signal is denoted as S, having a length of L_{S}; sampled points are denoted as P; and every Nᵥ points are sampled to obtain a vertex Vₖ;
Vₖ=max{Pᵢ}−min{Pⱼ}, wherein, (k−1)*Nᵥ+1≤i, j≤k*Nᵥ,k*N≤Lₛ;
step 2: starting recording when the vertex obtained by down-sampling satisfies a condition C₁: (Vₖ>Vₖ₋₁ and Vₖ>Vₖ₊₁)or(Vₖ>Vₖ₋₁ and Vₖ<Vₖ₊₁);
step 3: merging two neighboring segments when satisfying C₂:

|s̅e̅c̅ₘ−s̅e̅c̅ₘ₋₁|<max(|S̅e̅c̅ₘ|,|S̅e̅c̅ₘ₋₁|)/10
wherein S̅e̅c̅ₘ̅denotes a mean of all points sampled in an m-th segment; and
step 4: detecting the standby current and the overshoot current:
determining a current of an i-th segment to be in a standby state when the current of the i-th segment satisfies the following condition:
S̅e̅c̅ᵢ̅<P10{Vₖ}, and
determining the i-th segment Secᵢ to be an overshoot current segment when the i-th segment satisfies the following condition:
S̅e̅c̅ᵢ̅>2·max(S̅e̅c̅ᵢ̅₋̅₁̅,S̅e̅c̅ᵢ̅₊̅₁̅)

3. The current signal segmentation algorithm according to claim 1, wherein the step of extracting the shape distribution feature of the working current segment comprises:
step 1: extracting a value distribution class feature:
$${S}_{i}^{1} ( Se {c}_{k} ) = \# ( {P}_{j} ) / \# ( Se {c}_{k} ) , i = 1 , 2 , 3 , 4 , 5$$
$${P}_{j} ∈ S e {c}_{k} and {P}_{j} ∈ [ min ( S e {c}_{k} ) + \frac{max ( S e {c}_{k} ) - min ( S e {c}_{k} )}{5} \cdot ( i - 1 ) , min ( {Sec}_{k} ) + \frac{max ( S e {c}_{k} ) - min ( S e {c}_{k} )}{5} \cdot i ) ,$$
wherein, #( ) denotes a number of points in a set in parentheses, and k denotes a k-th effective segment; and
step 2: extracting a spatial distribution class feature:
$${S}_{i}^{2} ( Se {c}_{k} ) = 2 \cdot \# ( {P}_{j} ) / \# ( Se {c}_{k} ) , i = 1 , 2 , 3 , 4 , 5$$
$${P}_{j} ∈ S e {c}_{k} and {P}_{j} \geq median ( {Sec}_{k} ) and {P}_{j} ∈ [ \text{} {Sec}_{k}^{start} + \frac{{Sec}_{k}^{end} - {Sec}_{k}^{start}}{5} \cdot ( i - 1 ) , {Sec}_{k}^{start} + \frac{{Sec}_{k}^{end} - {Sec}_{k}^{start}}{5} \cdot i ) ,$$
wherein, median(Secₖ) denotes a median of values of all points in the k-th effective segment Secₖ.

4. The current signal segmentation algorithm according to claim 1, wherein the step of extracting the statistical feature of the working current segment comprises:
step 1: labeling all vertices in a k-th effective segment Secₖ; and
step 2: calculating a mean, a median and a standard deviation of values of the all vertices.

5. The current signal segmentation algorithm according to claim 1, wherein the step of extracting the harmonic feature of the working current segment comprises:
step 1: harmonically transforming all points in a k-th effective segment Secₖ; and
step 2: using first 16 harmonics:
$$f ( i ) = F ( i ) / {\sum }_{i = 0}^{16} F ( i ) i = 0 , 1 , 2 , … 16$$
wherein, F(i) denotes a value of an i-th harmonic.

6. The current signal segmentation algorithm according to claim 1, wherein the step of calculating the similarity between the segment pair comprises:
assigning two segments each as A and B:
step 1: calculating 6 subsimilarities between the two segments:
$$Sim {i}_{1} ( A , B ) = \frac{{\sum }_{i = 1}^{5} min ( {S}_{i}^{1} ( A ) , {S}_{i}^{1} ( B ) )}{{\sum }_{i = 1}^{5} max ( {S}_{i}^{1} ( A ) , {S}_{i}^{1} ( B ) )}$$
$$Sim {i}_{2} ( A , B ) = \frac{{\sum }_{i = 1}^{5} min ( {S}_{i}^{2} ( A ) , {S}_{i}^{2} ( B ) )}{{\sum }_{i = 1}^{5} max ( {S}_{i}^{2} ( A ) , {S}_{i}^{2} ( B ) )}$$
$$Sim {i}_{3} ( A , B ) = \frac{min ( {\overline{Sec}}_{A} , {\overline{Sec}}_{B} )}{max ( {\overline{Sec}}_{A} , {\overline{Sec}}_{B} )}$$
$$Sim {i}_{4} ( A , B ) = \frac{min ( {σ}_{S e {c}_{A}} / {\overline{Sec}}_{A} , {σ}_{S e {c}_{B}} / {\overline{Sec}}_{B} )}{max ( {σ}_{S e {c}_{A}} / {\overline{Sec}}_{A} , {σ}_{S e {c}_{B}} / {\overline{Sec}}_{B} )}$$
$$Sim {i}_{5} ( A , B ) = \frac{min ( median ( {Sec}_{A} ) , median ( {Sec}_{B} ) )}{max ( median ( {Sec}_{A} ) , median ( {Sec}_{B} ) )}$$
$$Sim {i}_{6} ( A , B ) = \frac{{\sum }_{i = 0}^{16} min ( {f}_{i} ( A ) , {f}_{i} ( B ) )}{{\sum }_{i = 0}^{16} max ( {f}_{i} ( A ) , {f}_{i} ( B ) )} ,$$
and
step 2: calculating a combined similarity:
$$Similarity ( A , B ) = {\prod }_{i = 1}^{6} {Simi}_{i} ( A , B ) .$$

7. The current signal segmentation algorithm according to claim 1, wherein the step of deriving the maximum clique set in the similarity graph through the maximum clique search algorithm as the class from the automatic segmentation comprises:
denoting the similarity graph as G=(V,E), wherein V denotes a segment set of the current signal, and E denotes a similarity matrix, which is a symmetrical similarity matrix; and denoting a similarity threshold as Sₜₕ and a class set as C, cᵢ∈C,vₖ∈cᵢ, k∈{1,2, . . . |V|}:
step 1: initializing cᵢ=i and e_{i,i}=0;
step 2: when the class set C is updated:
setting a similarity between all vertexes belonging to a current class and the current class to 0;
setting a similarity e_{i,j} between all vertexes belonging to the current class in E to 0;
calculating a minimum similarity min_simi_{i,clique} between all vertexes and the vertexes in the current class;
taking a maximum value max(min_simi_{i,clique}) of all min_simi_{i,clique};
if max(min_simi_{i,clique})<Sₜₕ and max(E)>Sₜₕ, then:
creating a new class comprising initial members that two vertices corresponding to max(E);
setting a class label to a smaller value of the two vertices; and
deleting an origin class of the two vertices; or
if max(min_simi_{i,clique})≥Sₜₕ, then:
joining a vertex with the maximum value into the current class, and deleting an origin class thereof; and
step 3: renumbering the class label, and updating a class number.
